(19) United States
(12) Patent Application Publication
(10) Pub. No.: US 2005/0060676 A1
(43) Pub. Date: Mar. 17, 2005

(54) Semiconductor integrated circuit and method for designing same

(76) Inventors: Yoichi Matsumura, Takatsuki (JP); Takako Ohashi, Otsu (JP); Katsuya Fujimura, Kameoka (JP); Chihiro Itoh, Nagaokakyo (JP); Hiroki Taniguchi, Kyoto (JP)

Correspondence Address: MCDERMOTT, WILL & EMERY, 600 13th Street, N.W., Washington, DC, 20005-3096, US

(21) Appl. No.: 10/817,959

(22) Filed: Apr. 6, 2004

(30) Foreign Application Priority Data
Sep. 12, 2003 (JP) 2003-322171

(51) Int. Cl. G06F 9/45; G06F 17/50; H03L 7/06

(52) U.S. Cl. 716/6; 703/19

(57) ABSTRACT

The present invention provides a semiconductor integrated circuit in which timing error is not likely to occur even if there is manufacturing variability. Logic cells 16 and 17, which are included in first and second clock circuits 11 and 12, respectively, are formed by transistors of a unified size. Even if there is manufacturing variability, delay time t₁ of the first clock circuit 11 and delay time t₂ of the second clock circuit 12 are increased or decreased by the same amount of time. Because of this, timing error is not likely to occur in a second flip-flop 15. A logic cell included in each clock cell may be formed by a transistor having a uniform rectangular-shaped diffusion region.

### BACKGROUND OF THE INVENTION

1. Field of the Invention

The present invention relates to a semiconductor integrated circuit, which operates in synchronization with a clock signal, and a method for designing such a semiconductor integrated circuit.

2. Description of the Background Art

In most cases, a semiconductor integrated circuit including a logic circuit operates in synchronization with an externally supplied clock signal or a clock signal which is internally generated based on an externally supplied signal. In general, the semiconductor integrated circuit includes a plurality of flip-flops and a circuit which generates a clock signal to be supplied to each flip-flop based on a supplied clock signal (hereinafter, such a circuit is referred to as a “clock circuit”). In order to allow the semiconductor integrated circuit to operate accurately, it is necessary to supply an appropriate clock signal to each flip-flop. Further, in order to reduce power consumption of the semiconductor integrated circuit, it is effective to stop supplying a clock signal to a circuit block which should not be operated. Accordingly, how the clock circuit is structured and how the clock signal is supplied are recognized as critical in designing the semiconductor integrated circuit.

In general, an analysis of the clock circuit focuses on portions of the clock circuit, such as paths through which clock signals flow (hereinafter, referred to as “clock paths”) and logic cells present on the clock paths, and a circuit tree including such portions is analyzed. This clock tree analysis calculates, for example, time periods taken for a supplied clock signal to reach flip-flops. Thereafter, in order for clock skew (a difference between the time periods taken for the supplied clock signal to reach the flip-flops) to be less than a prescribed tolerance, for example, processes for adding or deleting a buffer, etc., to/from the clock circuit and modifying a layout result are performed based on a result of the clock tree analysis.

A variety of types of conventional methods are known for supplying a clock signal within the semiconductor integrated circuit. Among such conventional methods, technology similar to the present invention is disclosed in Japanese Patent Laid-Open Publications Nos. 62-190747,4-284020, and 2000-68380, for example. Specifically, Japanese Patent Laid-Open Publication No. 62-190747 discloses a full flash type A/D converter in which one-bit comparators are alternately laid out upside down. Japanese Patent Laid-Open Publication No. 4-284020 discloses an inverter having a changeable threshold voltage. Japanese Patent Laid-Open Publication No. 2000-68380 discloses that the clock signal is routed through the bottom of a multiple wiring layers.

However, with the progress in fabrication of finer-sized semiconductor integrated circuits operable at a lower voltage, the level of technique required for supplying the clock signal within the semiconductor integrated circuit has become higher than before. For example, the progress in finer fabrication technology has reduced the size of a transistor which forms a logic cell included in a clock circuit. Accordingly, a delay time of the clock circuit tends to be more easily influenced by manufacturing variability, as compared to that of a conventional clock circuit. Further, the progress in finer fabrication technology has increased the integration scale of the clock circuit, and therefore it tends to take more time than before to perform the clock tree analysis or change the design of the clock circuit. Furthermore, with the progress in fabrication of finer-sized circuits operable at a lower voltage, the integration scale of the clock circuit becomes larger, while the delay time of the clock circuit is reduced in each stage of logic cells included in the clock circuit. Accordingly, in designing of the clock circuit, it is required to set a more appropriate design margin than conventionally required. In recent years, there are also circuits which are designed in consideration of variations in delay time due to deterioration over time. However, the clock signal is one of the most frequently changing signals, and therefore it is required to design the semiconductor integrated circuit after having correctly evaluated delay time variation of the clock signal due to deterioration over time.

### SUMMARY OF THE INVENTION

Therefore, an object of the present invention is to provide a semiconductor integrated circuit, which has advantages over a conventional semiconductor integrated circuit in supplying a clock signal, and a method for designing such a semiconductor integrated circuit.

The present invention has the following features to attain the object mentioned above.

A first aspect of the present invention is directed to a semiconductor integrated circuit in which logic cells included in clock circuits are formed by transistors of a unified size. Further, the logic cells included in the clock circuits may be formed by transistors each having a uniform rectangular-shaped diffusion region.

A second aspect of the present invention is directed to a semiconductor integrated circuit design method in which logic cells having a prescribed characteristic are used to design a clock circuit in a circuit block so as to operate under a first operating condition, and the logic cells included in the clock cell are replaced with logic cells having another prescribed characteristic, such that a designed semiconductor integrated circuit includes the circuit block after the replacement of logic cells, and operates under a second operating condition. In this case, the logic cells before and after the replacement are equivalent to each other in input capacitance, cell-specific delay and driving capability. The operating conditions are related to a threshold voltage, a supply voltage, etc.

A third aspect of the present invention is directed to a semiconductor integrated circuit design method in which the quantity of delay variation at the expiration of service life is obtained for each clock signal based on the number of toggles in the clock signal's service life, a difference in the quantity of delay variation between clock signals to be supplied to two storage cells is obtained, and circuit timing adjustment is performed in accordance with timing constraints between the two storage cells in which the obtained difference has been set as a design margin.

A fourth aspect of the present invention is directed to a semiconductor integrated circuit which includes: a toggle counting circuit for counting the number of toggles of a clock signal to be supplied to each circuit block; and a toggle count output circuit for outputting the counted number of toggles.

A fifth aspect of the present invention is directed to a semiconductor integrated circuit which includes: a toggle counting circuit for counting the number of toggles of a clock signal to be supplied to each circuit block; and a toggle adjustment circuit for supplying an adjustment clock signal to a circuit block to which a clock signal whose number of toggles is relatively low is supplied.

A sixth aspect of the present invention is directed to a semiconductor integrated circuit design method in which a type of logic cell which should be present on a clock path is designated, and a determination is made as to whether logic cells present on the clock path are of the designated type. Further, a type of logic cell, which should be present on the clock path, may be designated for each corresponding type of logic cell, which should not be present on the clock path. Then, based on a result of the determination, a logic cell, which should not be, but is, present on the clock path, may be replaced with a logic cell, which should be present on the clock path and whose type corresponds to that of the logic cell, which should not be, but is, present on the clock path.

A seventh aspect of the present invention is directed to a semiconductor integrated circuit design method in which prescribed characteristics are obtained for each clock path, and circuit timing adjustment is performed in accordance with timing constraints between two storage cells in which a design margin based on characteristics of two clock paths has been set. The design margin is obtained based on, for example, a difference in the number of stages of logic cells between the two clock paths, a difference in the number of each type of logic cells between the two clock paths, or types and delay times of wiring conductors present on the two clock paths.

According to the first aspect, it is possible to provide a semiconductor integrated circuit in which timing error is not likely to occur even if there is manufacturing variability. The effect of the first aspect is apparent particularly when the logic cells included in the clock circuits are formed by transistors each having a uniform rectangular-shaped diffusion region.

According to the second aspect, even if the operating condition of the circuit block is different from the operating condition of the semiconductor integrated circuit including the circuit block, it is possible to equalize threshold voltage levels or supply voltage levels of clock signals without re-adjusting the skew of the clock signals in the semiconductor integrated circuit after having incorporated the circuit block thereinto.

According to the third aspect, it is possible to more accurately set the design margin as compared to a conventional method. Therefore, it is possible to reduce a circuit size to less than a conventionally required circuit size, while taking account of variations of delay time of clock signals due to deterioration over time of transistors.

According to the fourth aspect, by obtaining the number of toggles of a clock signal to be supplied to each circuit block, it is made possible to obtain the probability of a change of the clock signal under the real operating environment in a short time period with high accuracy as compared to logical simulation or the like. Therefore, it is possible to redesign a semiconductor integrated circuit, in which timing error is not likely to occur, with more accurate consideration of the clock signal's delay time variation due to deterioration over time of transistors.

According to the fifth aspect, even after the semiconductor integrated circuit is incorporated into a system, by adjusting the number of toggles of each clock signal, it is made possible to prevent clock signals, which vary with frequencies different from each other, from being supplied. Once such clock signals are supplied, degrees of deterioration over time may become different between transistors, such that a timing error occurs, resulting in a shorter service life of the semiconductor integrated circuit.

According to the sixth aspect, it is possible to readily verify that logic cells present on a clock path have a specific characteristic (e.g., they are resistant to process variation). Further, by designating a type of logic cell, which should be present on the clock path, for each corresponding type of clock cell, which should not be, but is, present on the clock path, and replacing a logic cell of the designated type with a logic cell which should not be present on the clock path, it is made possible to change a clock circuit such that only the logic cells having a specific characteristic are present on the clock path.

According to the seventh aspect, even if there is a difference in the number of stages of logic cells between clock paths, it is possible to accurately set a design margin in accordance with a difference in structure between the clock paths, whereby it is possible to reduce a circuit size to less than a conventionally required circuit size.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing the structure of a semiconductor integrated circuit according to a first embodiment of the present invention;

FIG. 2 shows a layout of a transistor;

FIG. 3A is a diagram for showing a setup margin of a flip-flop;

FIG. 3B is a diagram for showing a hold margin of a flip-flop;

FIGS. 4A and 4B are graphs used for explaining an effect achieved by a semiconductor integrated circuit according to the first embodiment of the present invention;

FIGS. 5A through 5C are diagrams used for explaining an effect achieved by a semiconductor integrated circuit according to a variation of the first embodiment of the present invention;

FIG. 6 is a diagram showing the structure of a semiconductor integrated circuit designed by a method for designing a semiconductor integrated circuit in accordance with a second embodiment of the present invention;

FIG. 7 is a flowchart showing the method for designing a semiconductor integrated circuit in accordance with the second embodiment of the present invention;

FIG. 8 is a flowchart showing a method for designing a semiconductor integrated circuit in accordance with a third embodiment of the present invention;

FIG. 9 is a diagram showing a clock circuit designed by a method for designing a semiconductor integrated circuit in accordance with the third embodiment of the present invention;

FIG. 10 is a graph showing a relationship between the number of toggles and a variation rate of delay time in a transistor;

FIG. 11 is a diagram showing a structure of a semiconductor integrated circuit according to a fourth embodiment of the present invention;

FIG. 12 is a diagram showing another structure of the semiconductor integrated circuit according to the fourth embodiment of the present invention;

FIG. 13 is a diagram showing a structure of a semiconductor integrated circuit according to a fifth embodiment of the present invention;

FIG. 14 is a diagram showing a detailed structure of a toggle adjustment circuit of the semiconductor integrated circuit according to the fifth embodiment of the present invention;

FIG. 15 is a table showing an I/O relationship of a selector included in the toggle adjustment circuit of the semiconductor integrated circuit according to the fifth embodiment of the present invention;

FIG. 16 is a diagram showing an exemplary usage of the semiconductor integrated circuit according to the fifth embodiment of the present invention;

FIG. 17 is a flowchart showing a method for designing a semiconductor integrated circuit in accordance with a sixth embodiment of the present invention;

FIG. 18 is a flowchart showing a method for designing a semiconductor integrated circuit in accordance with a variation of the sixth embodiment of the present invention;

FIG. 19 is a flowchart showing a method for designing a semiconductor integrated circuit in accordance with a seventh embodiment of the present invention;

FIG. 20 is a diagram showing a clock circuit designed by the method for designing a semiconductor integrated circuit in accordance with the seventh embodiment of the present invention;

FIG. 21 is a flowchart showing a method for designing a semiconductor integrated circuit in accordance with a second variation of the seventh embodiment of the present invention; and

FIG. 22 is a diagram showing a clock circuit designed by the method for designing a semiconductor integrated circuit in accordance with the second variation of the seventh embodiment of the present invention.

### DESCRIPTION OF THE PREFERRED EMBODIMENTS

Hereinafter, first through seventh embodiments of the present invention will be described with reference to the accompanying drawings. For ease of understanding of the present invention, each embodiment is described with respect to, among all circuits included in a semiconductor integrated circuit, only primary circuits the descriptions of which are considered as being essential in understanding of the present invention.

(First Embodiment)

A first embodiment of the present invention is described with respect to a semiconductor integrated circuit in which logic cells included in clock circuits are formed by transistors of a unified size. FIG. 1 is a diagram showing the structure of the semiconductor integrated circuit according to the present embodiment. The semiconductor integrated circuit shown in FIG. 1 includes a first clock circuit 11, a second clock circuit 12, a first flip-flop 13, a combinational circuit 14, and a second flip-flop 15. Each of the first and second flip-flops 13 and 15 operates in synchronization with a clock signal CK supplied thereto. Specifically, the first clock circuit 11 generates a first clock signal CK₁ based on the clock signal CK, and the first flip-flop 13 operates in synchronization with the first clock signal CK₁. The second clock circuit 12 and the second flip-flop 15 operate similar to the first clock circuit 11 and the first flip-flop 13, respectively. The combinational circuit 14 generates a data input signal to be supplied to the second flip-flop 15, based on a value stored in the first flip-flop 13 and a value(s) stored in a flip-flop(s) not shown in FIG. 1.

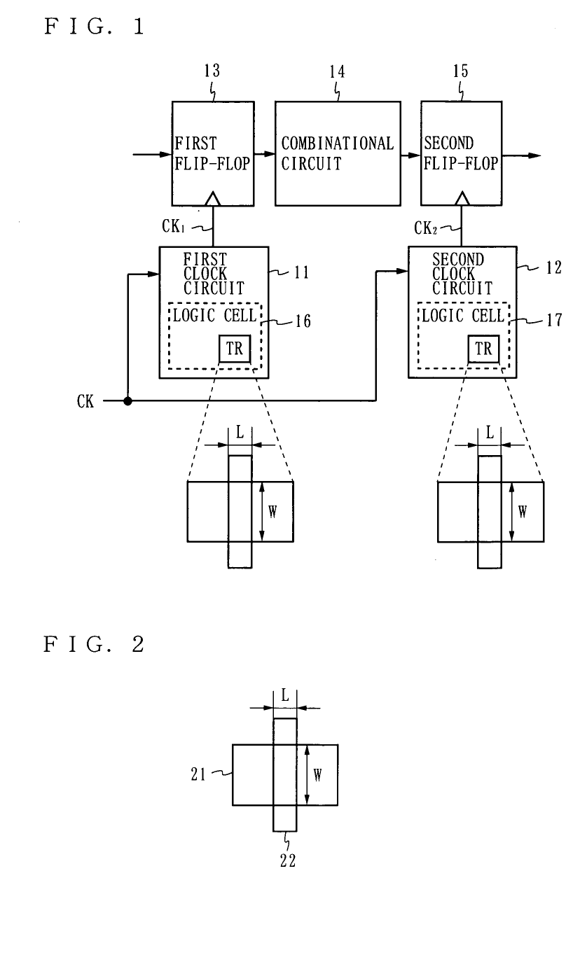

Each circuit included in the semiconductor integrated circuit includes one or more logic cells, and each logic cell is formed by one or more transistors. FIG. 2 shows a layout of a transistor. From the layout shown in FIG. 2, it is appreciated that the transistor is formed where a diffusion region 21 and a polysilicon region 22 overlap with each other. The characteristic of the transistor is determined by, for example, dimensions (i.e., channel width W and channel length L) of a region where the diffusion region 21 and the polysilicon region 22 overlap with each other.

As shown in FIG. 1, the first clock circuit 11 includes a logic cell 16, and the second clock circuit 12 includes a logic cell 17. The semiconductor integrated circuit according to the present embodiment is characterized in that the logic cells 16 and 17 respectively included in the first and second clock circuits 11 and 12 are formed by transistors having a unified dimension. Typically, the logic cells 16 and 17 are formed by transistors having a unified channel width W, but the transistors may have a unified channel width W and a unified channel length L.

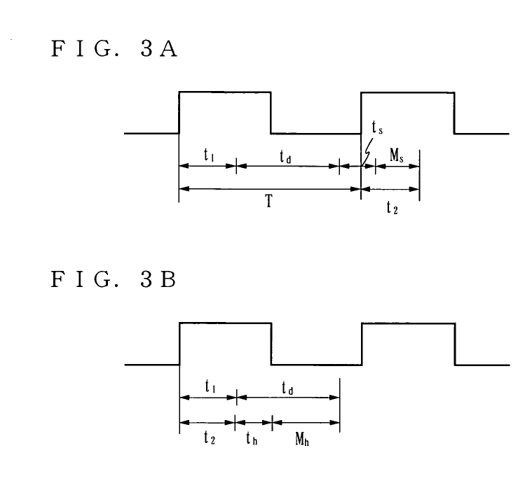

Described below is an effect achieved by the semiconductor integrated circuit according to the present embodiment in which the logic cells 16 and 17 included in the first and second clock circuits 11 and 12 are formed by transistors having a unified channel width W. In FIG. 1, the cycle of the clock signal CK is T, a delay time of the first clock circuit 11 is t₁, a delay time of the second clock circuit 12 is t₂, the sum of a delay time of the combinational circuit 14 and a delay time of the first flip-flop 13 between input of a clock signal and output of a data output signal is t_{d}, and a setup time and a hold time of the second flip-flop 15 are tₛ and tₕ, respectively. In this case, in order for the second flip-flop 15 to operate normally in synchronization with a second clock signal CK₂, a setup margin Mₛ and a hold margin Mₕ respectively shown below in expressions (1) and (2) are each required to be a positive value equal to or more than a prescribed value (see FIGS. 3A and 3B).
Mₛ=(t₂−t₁)+T−t_{d}−tₛ (1)
Mₕ=(t₁−t₂)+t_{d}−tₕ (2)

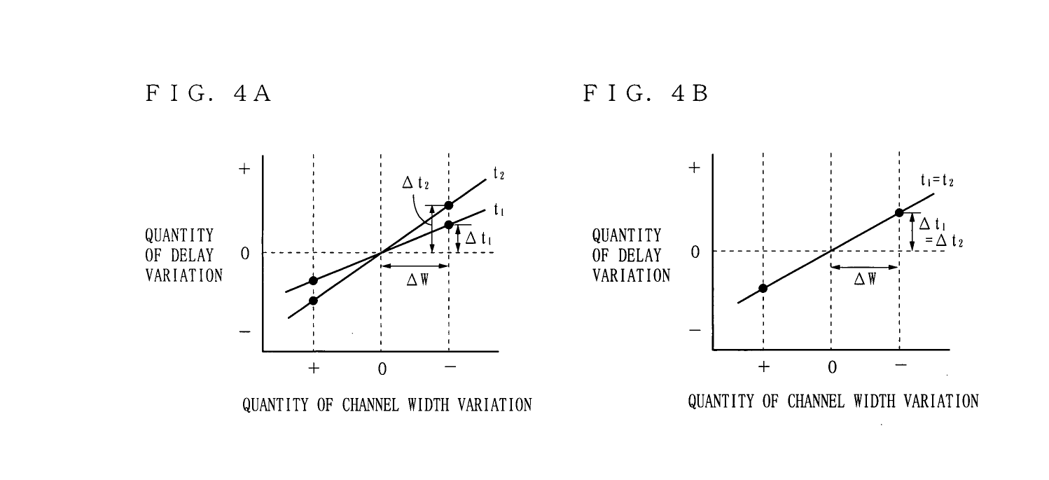

Regarding transistors included in the semiconductor integrated circuit, relationships between the quantity of variation of the channel width W and the quantity of variation of a delay time are shown in FIGS. 4A and 4B. FIG. 4A is a graph showing such a relationship for a transistor included in a conventional semiconductor integrated circuit, while FIG. 4B is a graph showing such a relationship for a transistor included in the semiconductor integrated circuit according to the present embodiment.

Now consider a case where a semiconductor integrated circuit having a structure as show in FIG. 1 is designed and fabricated using a conventional technique. In the semiconductor integrated circuit based on the conventional technique, logic cells included in clock circuits are formed by transistors which do not have a unified channel width W. A designed value for the channel width of a transistor which forms the logic cell 16 included in the clock circuit 11 is W₁, and a designed value for the channel width of a transistor which forms the logic cell 17 included in the clock circuit 12 is W₂. In this case, W₁ is assumed to be greater than W₂. Moreover, in the fabricated semiconductor integrated circuit, the channel width of each transistor is assumed to vary by ΔW from the designed value due to manufacturing variability. In such a case, the channel width of a fabricated transistor of the logic cell 16 included in the first clock circuit 11 is (W₁+ΔW), and the channel width of a fabricated transistor of the logic cell 17 included in the second clock circuit 12 is (W₂+ΔW). If W₁ is greater than W₂, the degree of variation in channel width due to manufacturing variability is greater in the transistor included in the logic cell 17 than in the transistor included in the logic cell 16.

Accordingly, in the semiconductor integrated circuit based on a conventional technique, if there is manufacturing variability, the delay time t₂ of the second clock circuit 12 varies more than a variation of the delay time t₁ of the first clock circuit 11 (see FIG. 4A). Accordingly, if an actually measured value of the channel width is greater than the designed value (i.e., if ΔW is a positive value), the delay time t₂ of the second clock circuit 12 is decreased more than a decrease of the delay time t₁ of the first clock circuit 11. Therefore, the value of (t₂−t₁) in the above expression (1) is decreased, resulting in an insufficient setup margin in the second flip-flop 15. On the other hand, if the actual channel width is less than the designed value (i.e., if ΔW is a negative value), the delay time t₂ of the second clock circuit 12 is increased more than an increase of the delay time t₁ of the first clock circuit 11. Accordingly, the value of (t₁−t₂) in the above expression (2) is decreased, resulting in an insufficient hold margin in the second flip-flop 15. In this manner, if the logic cells included in the clock circuits are formed by the transistors which do not have a unified channel width, timing error due to manufacturing variability may easily occur in the second flip-flop 15.

On the other hand, in the semiconductor integrated circuit according to the present embodiment, logic cells included in clock circuits are formed by transistors having a unified channel width W. That is, a designed value W₁ for the channel width of a transistor which forms the logic cell 16 included in the first clock circuit 11 is always equivalent to a designed value W₂ for the channel width of a transistor which forms the logic cell 17 included in the second clock circuit 12. Accordingly, even if there is manufacturing variability, the delay time t₁ of the first clock circuit 11 and the delay time t₂ of the second clock circuit 12 are increased or decreased by the same amount of time (see FIG. 4B). Accordingly, even if there is manufacturing variability, the value of (t₂−t₁) in the above expression (1) and the value of (t₁−t₂) in the above expression (2) do not vary from the designed value, and therefore timing error is not likely to occur in the second flip-flop 15.

Therefore, the present embodiment is able to provide a semiconductor integrated circuit in which timing error is not likely to occur even if there is manufacturing variability. The same effect can be achieved by a semiconductor integrated circuit in which logic cells included in clock circuits are formed by transistors having a unified channel width W and a unified channel length L.

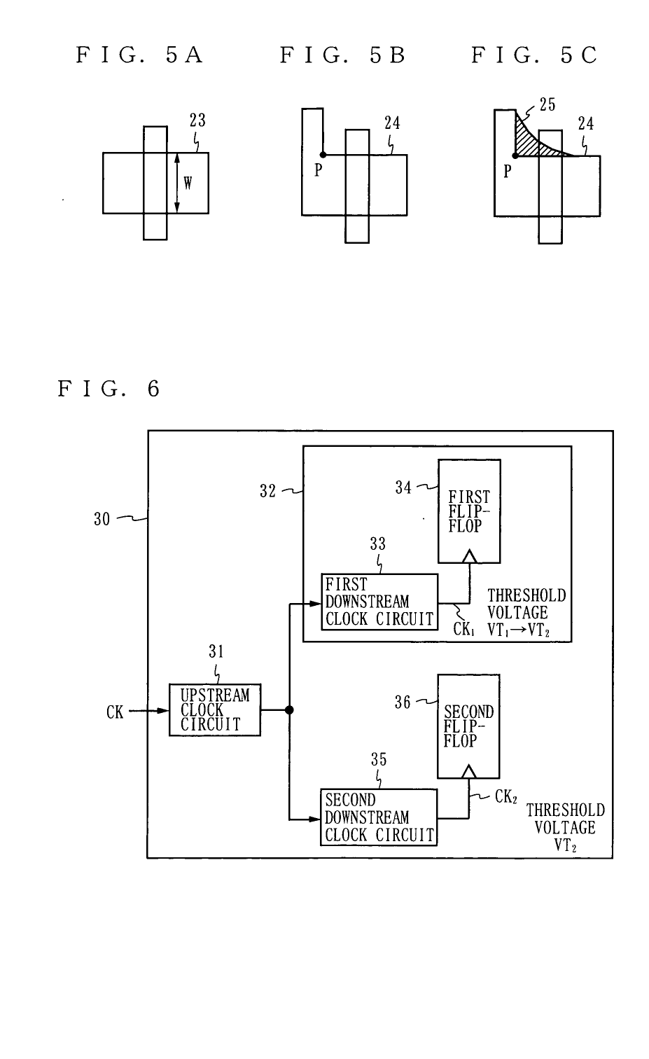

The following variation can be introduced to the semiconductor integrated circuit according to the present embodiment. A semiconductor integrated circuit according to a variation of the present embodiment is characterized in that logic cells included in clock circuits are formed by transistors of a unified size simultaneously with a uniform rectangular-shaped diffusion region 23 (see FIG. 5A).

An effect of the semiconductor integrated circuit according to the present variation is described below with reference to FIGS. 5A through 5C. FIG. 5B shows a layout of a transistor having a non-rectangular diffusion region 24. If a semiconductor integrated circuit including the transistor shown in FIG. 5B is fabricated, as shown in FIG. 5C, an unwanted diffusion region 25 (shown as a hatched region) is formed around the hollow vertex P of the diffusion region 24 in an area where no diffusion region is supposed to be formed (note that 270 degrees out of 360 degrees around the vertex P constitute the diffusion region 24). The unwanted diffusion region 25 may influence the channel width W of the transistor depending on its size and shape, thereby influencing the delay time of a circuit including the transistor.

Accordingly, for example, in the case where the logic cell 16 included in the first clock circuit 11 is formed by a transistor having a rectangular-shaped diffusion region 23 (see FIG. 5A) and the logic cell 17 included in the second clock circuit 12 is formed by the transistor having the diffusion region 24 with the hollow vertex P (see FIG. 5B), the unwanted diffusion region 25 formed during a fabrication process (see FIG. 5C) may influence the semiconductor integrated circuit such that a difference between the delay time t₁ of the first clock circuit 11 and the delay time t₂ of the second clock circuit 12 differs from a designed value. Consequently, a required temporal relationship is not satisfied between the delay time t₁ of the first clock circuit 11 and the delay time t₂ of the second clock circuit 12, so that timing error is likely to occur in the second flip-flop 15, etc.

On the other hand, in the semiconductor integrated circuit according to the present variation, the logic cells included in clock circuits are formed by transistors having a uniformly rectangular-shaped diffusion region 23 (see FIG. 5A). The diffusion region having such a characteristic does not have a hollow vertex P as shown in FIG. 5C, the unwanted diffusion region 25 is not formed around the hollow vertex P. Accordingly, the delay time t₁ of the first clock circuit 11 and the delay time t₂ of the second clock circuit 12 are increased or decreased by the same amount of time even if there is manufacturing variability. Therefore, the present variation is able to provide a semiconductor integrated circuit in which timing error is further unlikely to occur as compared to the semiconductor integrated circuit according to the first embodiment.

(Second Embodiment)

A second embodiment of the present invention is described with respect to a design method which uses a circuit block, which is designed to operate under a prescribed operating condition, to design a semiconductor integrated circuit so as to operate under an operating condition different from that of the circuit block. Described first is a design method which uses a circuit block, which is designed to operate at a prescribed threshold voltage, to design a semiconductor integrated circuit so as to operate at a threshold voltage different from that of the circuit block (see FIG. 6). A semiconductor integrated circuit 30 shown in FIG. 6 includes an upstream clock circuit 31, a circuit block 32, a second downstream clock circuit 35, and a second flip-flop 36. The semiconductor integrated circuit 30 is designed to operate at a prescribed threshold voltage (hereinafter, referred to as a “second threshold voltage VT₂”). The circuit block 32 includes a first downstream clock circuit 33 and a first flip-flop 34. The circuit block 32 is originally designed so as to operate at a threshold voltage, which is different from the second threshold voltage VT₂, (hereinafter, referred to as a “first threshold voltage VT₁”).

In FIG. 6, each of the first and second flip-flops 34 and 36 operates in synchronization with a clock signal CK supplied thereto. Specifically, the upstream clock circuit 31 and the first downstream clock circuit 33 collectively generate a first clock signal CK₁ based on the clock signal CK, and the first flip-flop 34 operates in synchronization with the first clock signal CK₁. The second downstream clock circuit 35 and the second flip-flop 36 operate similar to the first downstream clock circuit 33 and the first flip-flop 34, respectively.

FIG. 7 is a flowchart showing a method for designing a semiconductor integrated circuit in accordance with the present embodiment. Prior to implementation of the procedure shown in FIG. 7, logic cells designed to operate at the first threshold voltage V₁ (hereinafter, referred to as “first clock cells”) and logic cells designed to operate at the second threshold voltage V₂ (hereinafter, referred to as a “second clock cell”) are prepared for use in clock circuits. In this case, logic cells of the same type between the first and second clock cells are equivalent to each other in input capacitance, cell-specific delay, and drive capability. That is, the input capacitance of a first clock cell is equivalent to the input capacitance of a second clock cell of the same type as that of the first clock cell, the cell-specific delay of a first clock cell is equivalent to the cell-specific delay of a second clock cell of the same type as that of the first clock cell, and the drive capability of a first clock cell is equivalent to the drive capability of a second clock cell of the same type as that of the first clock cell. Note that the logic cells of the same type between the first and second clock cells may differ from each other in size.

After the first and second clock cells having characteristics as described above are prepared, the procedure shown in FIG. 7 is implemented. Firstly, the circuit block 32 is designed so as to operate at the first threshold voltage VT₁ (step S101). In this case, a clock circuit included in the circuit block 32 (i.e., a circuit which is later to become the first downstream clock circuit 33) is designed using the first clock cell. For example, the circuit block 32 may be a circuit designed as an intellectual property (IP) core, such that it can be incorporated into another semiconductor integrated circuit.

Next, in the circuit block 32 designed at step S101, the first clock cell included in the clock circuit is replaced with a second clock cell of the same type as that of the first clock cell (step S102). After replacement of the logic cell, the clock circuit becomes the first downstream clock circuit 33. In this manner, the circuit block 32 including the first downstream clock circuit 33 is obtained. Next, another semiconductor integrated circuit 30, which includes the circuit block 32 obtained at step S102, is designed so as to entirely operate at the second threshold voltage VT₂ (step S103).

Described below is an effect achieved by using a design method according to the present embodiment to design the semiconductor integrated circuit 30. Now consider a case, unlike the design method of the present embodiment, where logic cells without characteristics as described above are used to design a clock circuit included in the circuit block 32 when the circuit block 32 is designed so as to operate at the first threshold voltage VT₁. In the semiconductor integrated circuit 30, which is designed so as to include, as the first downstream clock circuit 33, the clock circuit designed as described above, clock skew due to a difference between threshold voltages is liable to occur between the first flip-flop 34, which is originally designed to operate at the first threshold voltage VT₁, and the second flip-flop 36, which is designed anew to operate at the second threshold voltage VT₂. Accordingly, in order to prevent the clock skew, it is necessary to re-adjust the skew of clock signals so as not to change the delay time t₁ of the first downstream clock circuit 33 due to a change of the threshold voltage (i.e., a change from the first threshold voltage VT₁ to the second threshold voltage VT₂) when circuit modification is carried out in order to equalize threshold voltages in the semiconductor integrated circuit 30 after having incorporated the circuit block 32 thereinto.

On the other hand, in the design method of the present embodiment, as described above, the first clock cell included in the first downstream clock circuit 33 and the second clock cell included in the second downstream clock circuit 35 have the same input capacitance, the same cell-specific delay, and the same drive capability if they are of the same type. Accordingly, the delay time t₁ of the first downstream clock circuit 33 does not change before and after the threshold voltage is changed. Therefore, clock skew equal to or more than its designed value does not occur between the first and second flip-flops 34 and 36. Thus, in the design method of a semiconductor integrated circuit according to the present embodiment, it is possible to equalize threshold voltages of clock signals without re-adjusting the skew of the clock signals in the semiconductor integrated circuit having the circuit block incorporated therein.

The present embodiment has been described so far with respect to a method which uses a circuit block, which is designed to operate at a prescribed threshold voltage, to design a semiconductor integrated circuit so as to operate at a threshold voltage different from that of the circuit block. Further, a design method similar to the above-described method can also be applied to a case where the circuit block and the semiconductor integrated circuit including the circuit block differ from each other in an operating condition, e.g., a supply voltage, other than the threshold voltage. For example, in order to design a semiconductor integrated circuit adapted to operate at the second supply voltage V₂ using a circuit block designed to operate at the first supply voltage V₁, a procedure similar to that shown in FIG. 7 may be performed after equalizing the first clock cell designed to operate at the first supply voltage V₁ and the second clock cell designed to operate at the second supply voltage V₂ in terms of input capacitance, cell-specific delay and drive capability. In this design method, even if the circuit block and the semiconductor integrated circuit having the circuit block incorporated therein differ from each other in supply voltage, it is possible to equalize supply voltages of clock signals without re-adjusting the skew of the clock signals in the semiconductor integrated circuit having the circuit block incorporated therein.

(Third Embodiment)

A third embodiment of the present invention is described with respect to a method for designing a semiconductor integrated circuit which takes account of variations in delay time of clock signals due to deterioration over time of transistors. In general, a transistor deteriorates depending on the length of time periods for which a prescribed signal voltage is applied thereto. Accordingly, a delay time of a circuit formed by transistors is increased with the passage of time. In most cases, the length of a time period for which a clock signal is at a high level is the same as the length of a time period for which the signal is at a low level. Accordingly, by counting the number of times when the clock signal is changed to a prescribed value (hereinafter, referred to as the “number of toggles”), it is possible to calculate the length of time periods for which the clock signal is at the prescribed value, whereby it is possible to previously estimate how much deterioration occurs based on the calculated length of such time periods.

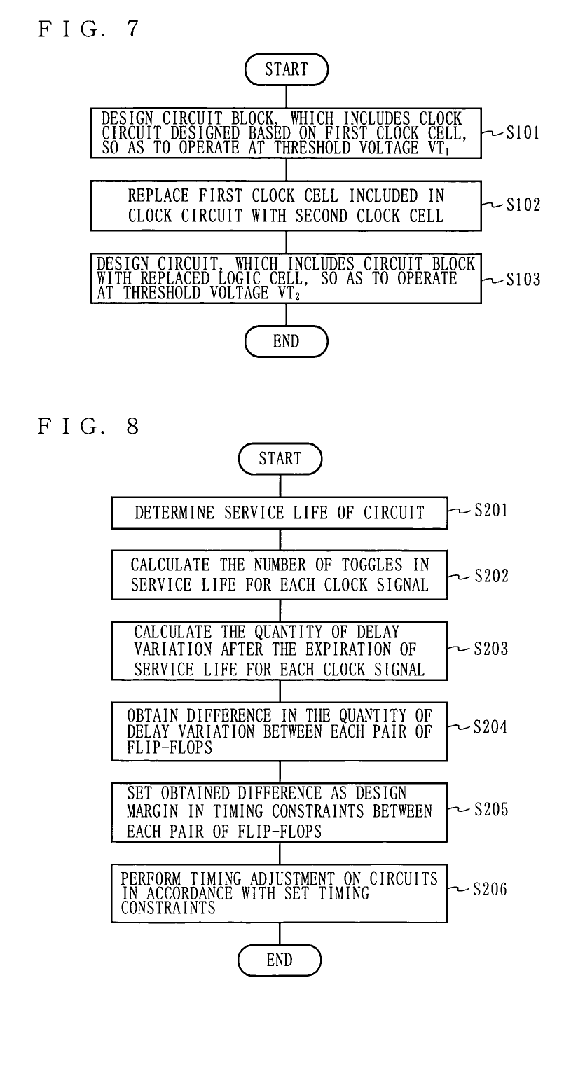

FIG. 8 is a flowchart showing a method for designing a semiconductor integrated circuit in accordance with the present embodiment. The procedure shown in FIG. 8 is performed on a semiconductor integrated circuit after the completion of logic level design and before timing adjustment. In the procedure of FIG. 8, firstly, the service life of a semiconductor integrated circuit to be designed is determined (step S201). The service life is determined as a value, e.g., three years, ten years, etc., based on specifications and operating conditions of the semiconductor integrated circuit.

The semiconductor integrated circuit to be designed includes a plurality of flip-flops. Accordingly, the number of toggles in the service life determined at step S201 is then calculated for each clock signal supplied to the flip-flops (step S202). The number of toggles TC of a clock signal to be supplied to a flip-flop FX is calculated by, for example, the following expression (3),
TC=TX×FR×α (3).

In the above expression (3), TX represents the service life determined at step S201, FR represents a frequency of a supplied clock signal CK, and α represents the probability of change of the clock signal to be supplied to the flip-flop FX when the clock signal CK is changed (hereinafter, referred to as the “toggle probability”). The toggle probability α is calculated or estimated based on the specifications and operating conditions of the semiconductor integrated circuit. The toggle probability may also be obtained by logic simulation, for example.

Note that when obtaining the number of toggles of the clock signal, a change of the clock signal only in a direction from a low level to a high level or only in an opposite direction may be counted as a single toggle. Alternatively, a change of the clock signal in each direction may be counted as a single toggle. For example, in the following descriptions, a change of the clock signal only in a direction from a low level to a high level is counted as a single toggle.

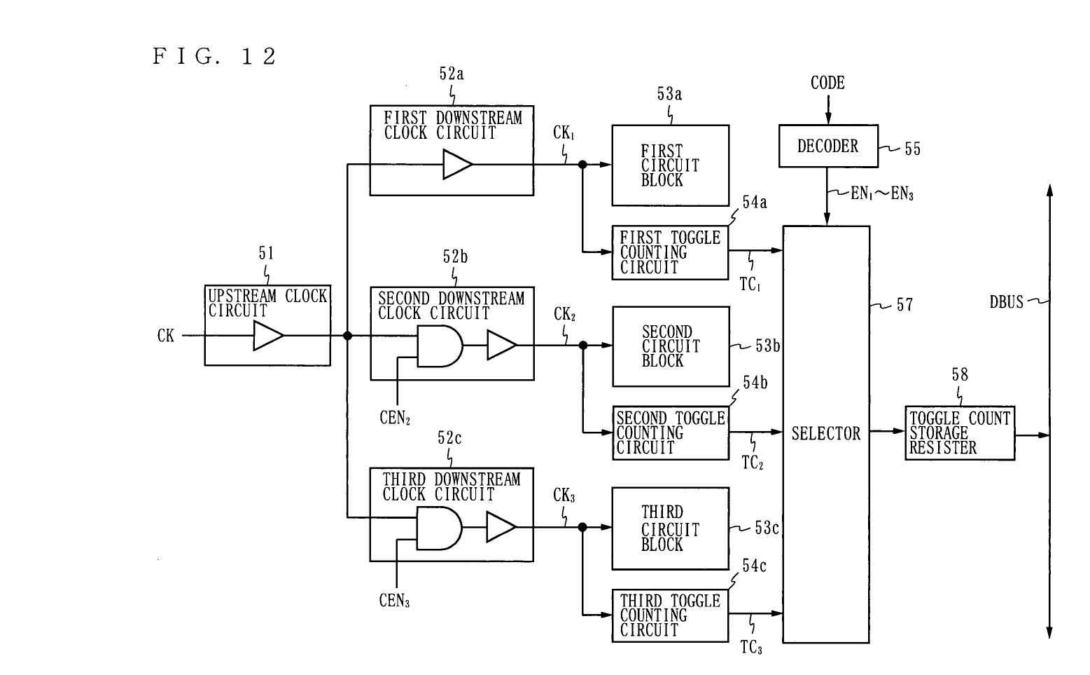

Next, for each clock signal to be supplied to the flip-flops, the quantity of delay variation at the expiration of service life is calculated based on the number of toggles obtained at step S202 (step S203). If the length of time periods for which the clock signal is at a low level is the same as the length of time periods for which the clock signal is at a high level, a relationship between the number of toggles and a variation rate of a delay time for a clock signal can be obtained for a transistor included in a logic cell to which the clock signal is inputted, based on characteristics of the transistor (see FIG. 10 which will be described later). Accordingly, at step S203, the quantity of delay variation at the expiration of service life can be obtained based on the number of toggles obtained at step S202 and the relationship between the number of toggles and a delay variation rate obtained for each transistor.

Next, pairs of flip-flops are sequentially selected from the semiconductor integrated circuit to be designed, and for each pair of flip-flops, a difference between the quantity of delay variation obtained for a clock signal to be supplied to one flip-flop and the quantity of delay variation obtained for a clock signal to be supplied to the other flip-flop is obtained (step S204). Then, the obtained difference in the quantity of delay variation is set as a design margin for accommodating a delay time variation due to deterioration over time, in timing constraints between the selected pair of flip-flops (step S205). Note that at steps S204 and S205, a difference in the quantity of delay variation may be obtained only for a pair/pairs of flip-flops having timing constraints assigned thereto, and the obtained difference may be set in the timing constraints.

Next, timing adjustment is performed on circuits which supply the clock signal and the data input signal to the flip-flops, in accordance with the timing constraints in which the design margin has been set in a manner as described above (step S206). At step S206, for example, a process for adding or deleting a buffer, etc., to/from the clock circuit, a process for redesigning a circuit for generating the data input signal, and/or a process for modifying a layout result is/are performed such that clock skew is less than a prescribed tolerance.

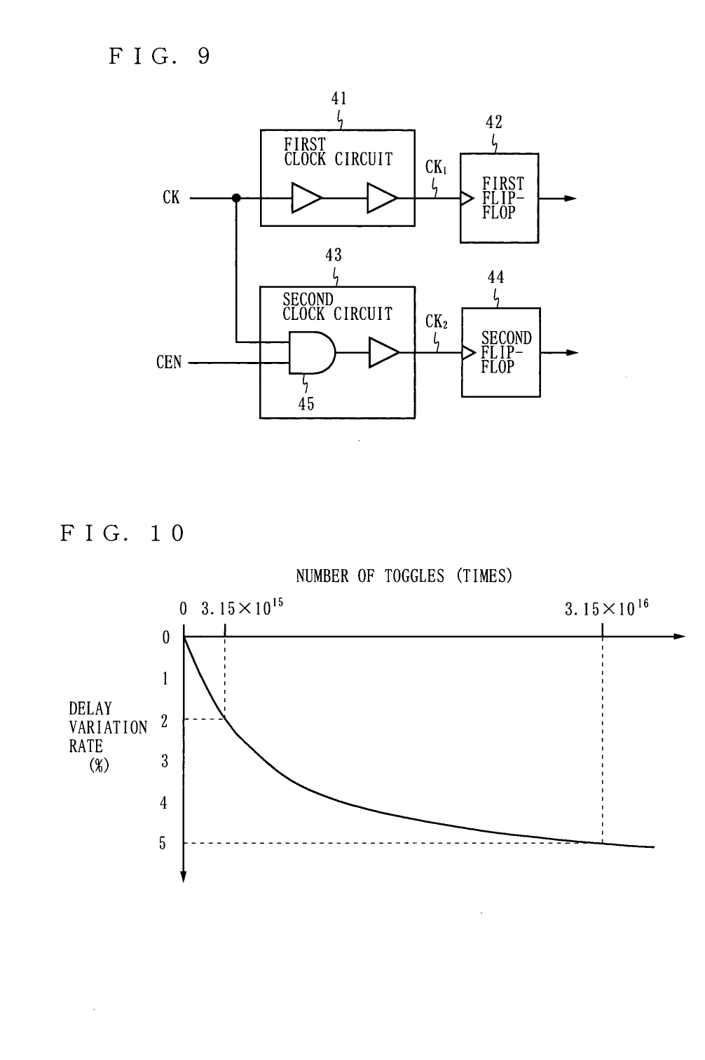

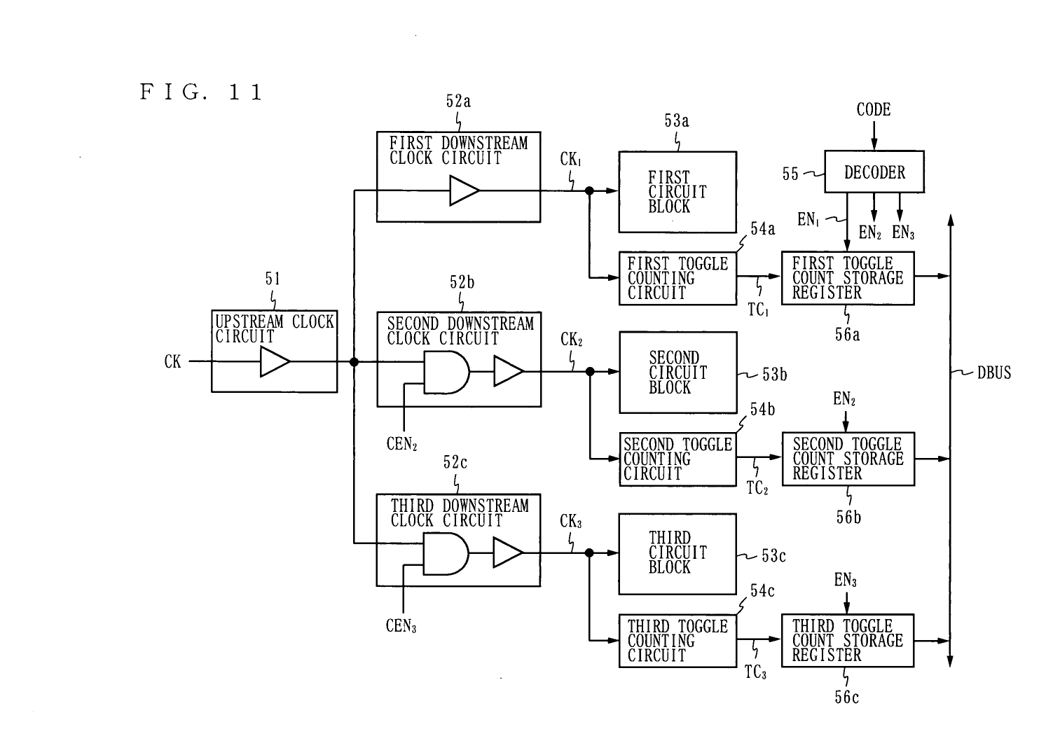

Next, detailed descriptions are provided for a case where the procedure of FIG. 8 is applied to a semiconductor integrated circuit including a clock circuit shown in FIG. 9. The clock circuit shown in FIG. 9 includes a first clock circuit 41, a first flip-flop 42, a second clock circuit 43, and a second flip-flop 44. Each of the first and second flip-flops 42 and 44 operates in synchronization with a clock signal CK supplied thereto. Specifically, the first clock circuit 41 includes two buffers, and generates, based on the clock signal CK, a first clock signal CK₁ which is changed with the same frequency as the frequency of change of the clock signal CK. The first flip-flop 42 operates in synchronization with the first clock signal CK₁. The second clock circuit 43 includes an AND gate 45 and a buffer. The second clock circuit 43 generates, based on the clock signal CK, a second clock signal CK₂ which is changed with a frequency lower than the frequency of change of the clock signal CK. The second flip-flop 44 operates in synchronization with the second clock signal CK₂. The AND gate 45 is supplied with the clock signal CK and a clock enable signal CEN. In the following descriptions, the frequency of the clock signal CK is 100 MHz, and the clock enable signal CEN becomes high level at the ratio of one to every ten cycles of the clock signal CK.

The service life of the semiconductor integrated circuit including the clock circuit shown in FIG. 9 is determined as, for example, ten years (step S201 of FIG. 8). Ten years correspond to about 3.15×10⁸ seconds. Accordingly, the number of toggles TC₁ of the first clock signal CK in ten years of use is obtained as 3.15×10¹⁶ by expression (4) shown below. The toggle probability α of the second clock signal CK₂ is one in ten, and therefore the number of toggles TC₂ of the second clock signal CK₂ in ten years of use is obtained as 3.15×10¹⁵ by expression (5) shown below (step S202).
TC₁≈(3.15×10⁸)×(100×10⁶)×1=3.15×10¹⁶ (4)
TC₂≈(3.15×10⁸)×(100×10⁶)×1/10=3.15×10¹⁵ (5)

In a transistor which forms a logic cell included in the clock circuit shown in FIG. 9, delay time may vary, as shown in FIG. 10, in accordance with the number of toggles of an input signal. In FIG. 10, the horizontal axis indicates the number of toggles of the input signal, and the vertical axis indicates a delay time variation rate. Since the number of toggles TC₁ of the first clock signal CK₁ in ten years of use is 3.15×10¹⁶, as shown in FIG. 10, a delay variation rate for the first clock signal CK₁ after the tenth year of use is 5%. On the other hand, the number of toggles TC₂ of the second clock signal CK₂ in ten years of use is 3.15×10¹⁵, and therefore, as shown in FIG. 10, the quantity of delay variation of the second clock signal CK₂ after the tenth year of use is 2%. That is, upon the expiration of service life of ten years, the delay time t₁ of the first clock signal CK₁ is increased by 5% from the initial delay time, while the delay time t₂ of the second clock signal CK₂ is increased by 2% from the initial delay time (step S203). Accordingly, the difference between the quantity of delay variation of the first clock signal CK₁ and the quantity of delay variation of the second clock signal CK₂ becomes 3% (step S204).

Accordingly, the obtained difference in the quantity of delay variation of 3% is set, as a design margin for accommodating a delay time variation due to deterioration over time, in timing constraints between the first and second flip-flops 42 and 44, (step S205). Then, timing adjustment is performed on circuits, which supply the clock signal and the data input signal to the first and second flip-flops 42 and 44, in accordance with the timing constraints in which the design margin of 3% has been set (step S206).

Described below is an effect achieved by designing a semiconductor integrated circuit including the clock circuit shown in FIG. 9 using a design method according to the present embodiment. In a conventional method, when a design margin for accommodating a delay time variation due to deterioration over time is set in timing constraints between flip-flops, a worst case value of the quantity of delay variation is set for each clock signal supplied to the flip-flops. Accordingly, in timing constraints between the first and second flip-flops 42 and 44, a value of 5 percent, which is the worst case value selected from among the variation rate of 5% for the delay time t₁ of the first clock signal CK₁ and the variation rate of 2% for the delay time t₂ of the second clock signal CK₂, is set as the design margin.

On the other hand, in the design method according to the present embodiment, as the design margin for accommodating a delay time variation due to deterioration over time, a difference between quantities of delay variation of clock signals supplied to flip-flops is set in the timing constraints between the flip-flops. Accordingly, in the timing constraints between the first and second flip-flops 42 and 44, a value of 3%, which corresponds to a difference between the variation rate of 5% for the delay time t₁ of the first clock signal CK₁ and the variation rate of 2% for the delay time t₂ of the second clock signal CK₂, is set as the design margin.

In an actual semiconductor integrated circuit, when the delay time t₁ of the first clock signal CK₁ is increased by 5% after the expiration of a 10-year service life, the delay time t₂ of the second clock signal CK₂ is also increased by 2%. Accordingly, in the timing constraints between the first flip-flop 42, which operates in synchronization with the first clock signal CK₁, and the second flip-flop 44, which operates in synchronization with the second clock signal CK₂, it is sufficient to set the difference between the quantities of delay variation (i.e., 3%), rather than the worst case value selected from among the quantities of delay variation (i.e., 5%), as the design margin for accommodating a delay time variation due to deterioration over time. By designing a semiconductor integrated circuit using the difference between the quantities of delay variation, which has been set as the design margin for accommodating a delay time variation due to deterioration over time, it is possible to ensure that the designed semiconductor integrated circuit operates normally within its service life.

Accordingly, in a method for designing a semiconductor integrated circuit in accordance with the present embodiment, it is possible to more accurately set the design margin as compared to a conventional method. Therefore, it is possible to reduce a circuit size to less than a conventionally required circuit size, while taking account of variations of delay time of clock signals due to deterioration over time of transistors.

(Fourth Embodiment)

A fourth embodiment of the present invention is described with respect to a semiconductor integrated circuit having a function of counting the number of toggles of the clock signal.

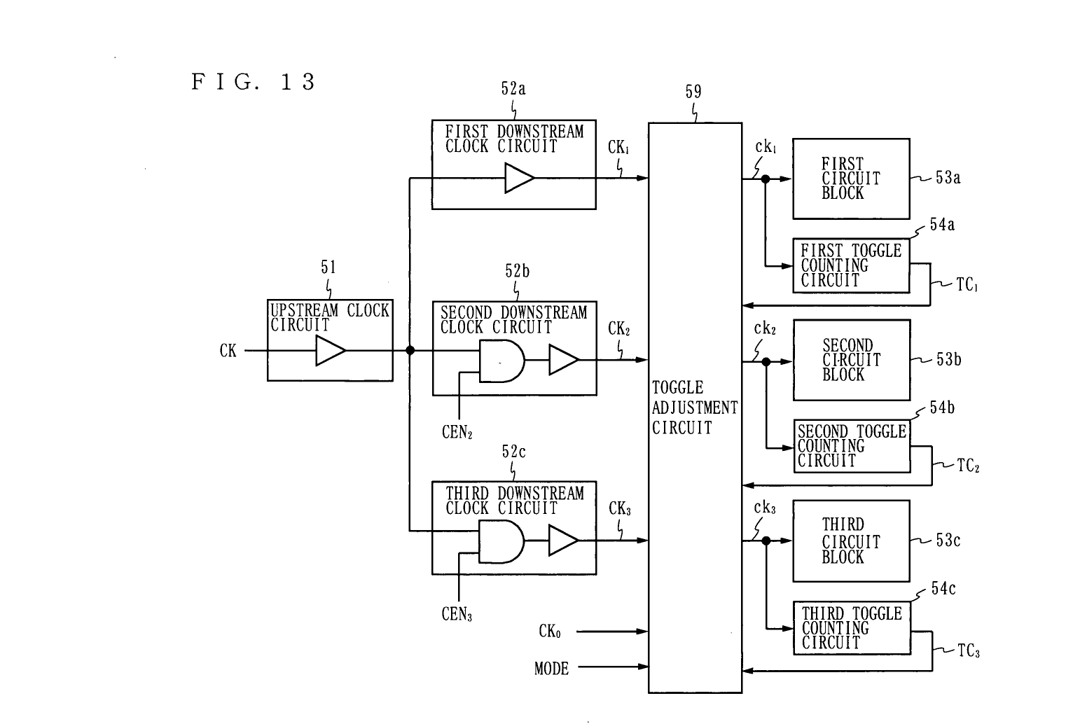

FIG. 11 is a diagram showing a structure of a semiconductor integrated circuit according to the present embodiment. The semiconductor integrated circuit shown in FIG. 11 includes an upstream clock circuit 51, first through third downstream clock circuits 52a through 52c, first through third circuit blocks 53a through 53c, first through third toggle counting circuits 54a through 54c, a decoder 55, and first through third toggle count storage registers 56a through 56c. Each of the first through third circuit blocks 53a through 53c operates in synchronization with a clock signal CK supplied thereto. Specifically, the upstream clock circuit 51 and the first downstream clock circuit 52a collectively generate a first clock signal CK₁ based on the clock signal CK, and the first circuit block 53a operates in synchronization with the first clock signal CK₁. The second and third downstream clock circuits 52b and 52c and the second and third circuit blocks 53b and 53c operate similar to the first downstream clock circuit 52a and the first circuit block 53a, respectively.

The first through third toggle counting circuits 54a through 54c count the number of toggles of the first through third clock signals CK₁ through CK₃, respectively. Here, a change of the clock signal from a low level to a high level is counted as a single toggle. The decoder 55 decodes a code signal CODE, and outputs enable signals EN₁ through EN₃ to the first through third toggle count storage registers 56a through 56c. Upon receipt of a corresponding one of enable signals EN₁ through EN₃, each of the first through third toggle count storage registers 56a through 56c reads a corresponding one of toggle counts TC₁, TC₂ and TC₃, respectively from the first through third toggle counting circuits 54a through 54c, and stores the read toggle count therein. The stored toggle counts are outputted from their respective storage registers in accordance with a timing specification of a data bus DBUS.

The toggle counts outputted over the data bus DBUS are outputted to the outside of the semiconductor integrated circuit. Therefore, in the toggle count output mode, the data bus DBUS is connected to, for example, an external I/O terminal (not shown) of the semiconductor integrated circuit. Alternatively, the toggle counts outputted over the data bus DBUS may be temporarily stored into a register connected to the data bus DBUS, and may be outputted via the register to the outside of the semiconductor integrated circuit. In this manner, the toggle counts TC₁ through TC₃ counted by the first through third toggle counting circuits 54a through 54c are outputted to the outside of the semiconductor integrated circuit through the operation of the decoder 55, the first through third toggle count storage registers 56a through 56c, and the data bus DBUS.

FIG. 12 is a diagram showing another structure of the semiconductor integrated circuit according to the present embodiment. The semiconductor integrated circuit shown in FIG. 12 includes the upstream clock circuit 51, the first through third downstream clock circuits 52a through 52c, the first through third circuit blocks 53a through 53c, the first through third toggle counting circuits 54a through 54c, the decoder 55, a selector 57, and a toggle count storage register 58. Among elements shown in FIG. 12, the same elements as those shown in FIG. 11 are denoted by the same reference numerals, and the descriptions thereof are omitted. Based on the enable signals EN₁ through EN₃ outputted from the decoder 55, the selector 57 reads toggle counts from either one of the first through third toggle count circuits 54a through 54c, and outputs the read toggle counts. The toggle count storage register 58 stores thereinto the toggle counts outputted from the selector 57, and outputs the stored toggle counts in accordance with a timing specification of the data bus DBUS.

Described next is an effect achieved by a semiconductor integrated circuit according to the present embodiment which has the structure shown in FIG. 11 or 12. The semiconductor integrated circuit according to the present embodiment is mounted on, for example, an evaluation board of a system. The evaluation board implements real application software under a real operating environment of the system. This allows the evaluation board to reproduce a real operation of the system.

As described above, the semiconductor integrated circuit of the present embodiment has a function of counting the number of toggles of a clock signal to be supplied to each circuit block and outputting the counted number of toggles to the outside of the semiconductor integrated circuit. Accordingly, when the evaluation board is used to reproduce the operation of the system, by obtaining the number of toggles of the clock signal to be supplied to each circuit block, it is made possible to obtain the probability of a change of the clock signal under the real operating environment (i.e., the toggle probability α) in a short time period with high accuracy as compared to logical simulation or the like.

As already described in the third embodiment, by determining the service life of the semiconductor integrated circuit and obtaining the toggle probability α of the clock signal going through the semiconductor integrated circuit, it is made possible to obtain the quantity of delay variation of the clock circuit at the expiration of the service life. Accordingly, when designing a new semiconductor integrated circuit, which has functions similar to those of the semiconductor integrated circuit of the present embodiment, as an improved version of the semiconductor integrated circuit of the present embodiment (or as a design target circuit based on an evaluation circuit), it is possible to design a clock circuit in consideration of the obtained quantity of delay variation. Therefore, it is possible to redesign the semiconductor integrated circuit, in which a timing error is not likely to occur, with more accurate consideration of the clock signal's delay time variation due to deterioration over time of transistors.

(Fifth Embodiment)

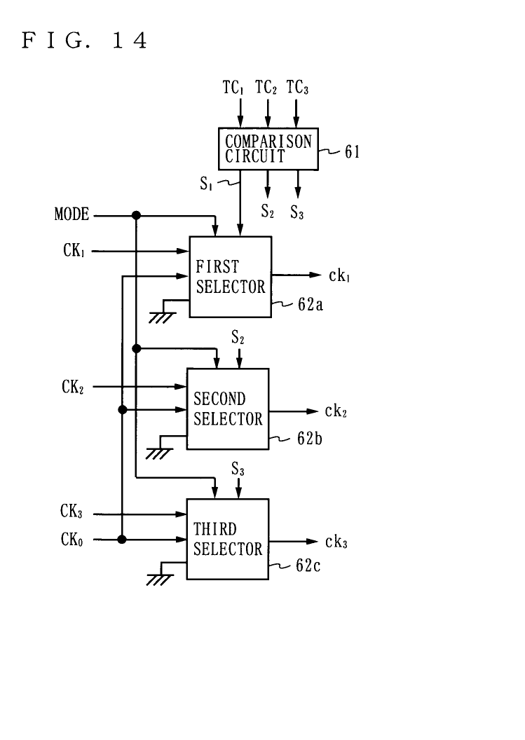

A fifth embodiment of the present invention is described with respect to a semiconductor integrated circuit having a function of adjusting the number of toggles of a clock signal. FIG. 13 is a diagram showing the structure of the semiconductor integrated circuit according to the present embodiment. The semiconductor integrated circuit shown in FIG. 13 includes the upstream clock circuit 51, the first through third downstream clock circuits 52a through 52c, the first through third circuit blocks 53a through 53c, the first through third toggle counting circuits 54a through 54c, and a toggle adjustment circuit 59. Among elements shown in FIG. 13, the same elements as those shown in FIG. 11 are denoted by the same reference numerals, and the descriptions thereof are omitted.

The toggle adjustment circuit 59 receives first through third clock signals CK₁ through CK₃ respectively outputted from the first through third downstream clock circuits 52a through 52c, an adjustment clock signal CK₀, a mode selection signal MODE, and the toggle counts TC₁ through TC₃ respectively counted by the first through third toggle counting circuits 54a through 54c. The toggle adjustment circuit 59 generates, based on these input signals, clock signals ck₀ through ck₃ to be supplied to the first through third circuit blocks 53a through 53c, respectively.

FIG. 14 is a diagram showing the detailed structure of the toggle adjustment circuit 59. The toggle adjustment circuit 59 includes a comparison circuit 61 and first through third selectors 62a through 62c. The comparison circuit 61 obtains select signals S₁ through S₃ for first through third selectors 62a through 62c based on the toggle counts TC₁ through TC₃. Specifically, in the case where a maximum possible value of each of the toggle counts TC₁ through TC₃ is M, when an i'th toggle count TCᵢ is the maximum value M (where i is an integer in the range from 1 to 3), the comparison circuit 61 supplies a high-level select signal Sᵢ to an i'th selector 62j (where if i=1, j=a, if i=2, j=b, and if i=3, j=c) to arrive at a high level, and if other wise, a low-level select signal Sᵢ is provided to the i'th selector 62j.

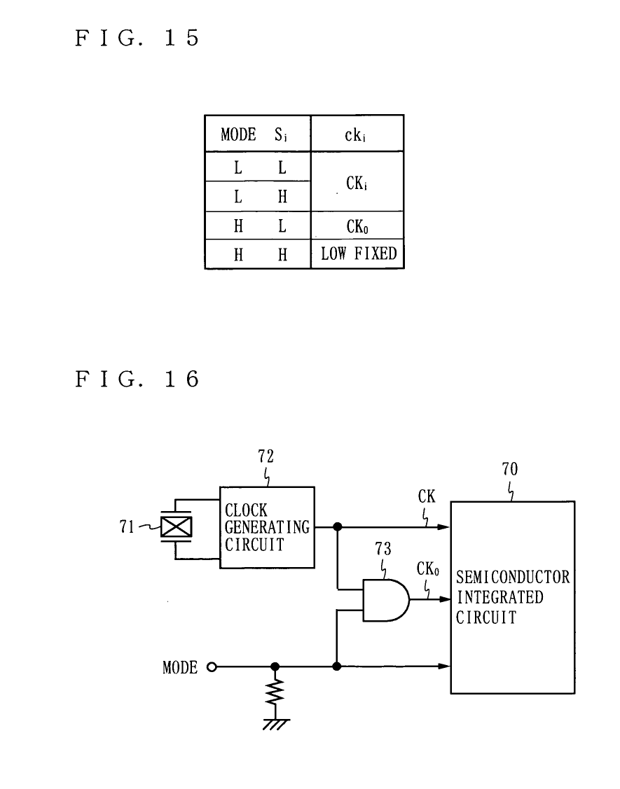

As is appreciated from FIG. 15, the first selector 62a outputs any one of the first clock signal CK₁, the adjustment clock CK₀, and a low-level fixed value, based on the mode selection signal MODE and the select signal Sᵢ. Specifically, if the mode selection signal MODE is at a low level (i.e., the signal indicates a normal operation mode), the first selector 62a outputs the first clock signal CK₁. If the mode selection signal MODE is at a high level (i.e., the signal indicates an adjustment mode) and the select signal S₁ is at a low level, the first selector 62a outputs the adjustment clock CK₀. If both the mode selection signal MODE and select signal S₁ are at a high level, the first selector 62a outputs the low-level fixed value. The second and third selectors 62b and 62c operate similar to the first selector 62a.

When in the normal operation mode, the thus-configured toggle adjustment circuit 59 outputs the first through third clock signals CK₁ through CK₃ to the first through third circuit blocks 53a through 53c, respectively. While in the adjustment mode, the toggle adjustment circuit 59 selects, from the first through third circuit blocks 53a through 53c, a circuit block to which a clock signal whose number of toggles is relatively low is supplied, and outputs the adjustment clock signal CK₀ to the selected circuit block.

FIG. 16 is a diagram showing an exemplary usage of a semiconductor integrated circuit according to the present embodiment. In FIG. 16, a semiconductor integrated circuit 70 is supplied with a clock signal CK generated by a crystal oscillator 71 and a clock generating circuit 72. An AND gate 73 is supplied with the clock signal CK and a mode selection signal MODE. A logical product of the clock signal CK and the mode selection signal MODE becomes the adjustment clock signal CK₀. Note that the clock generating circuit 72 and the AND gate 73 may be provided in the semiconductor integrated circuit 70.

The mode selection signal MODE is set by hardware or software included in a system, so as to be at a low level during a normal operation of the system. When the system is not in a normal operation, e.g., when the system is on standby or being recharged, the mode selection signal is set so as to be at a high level. When the mode selection signal MODE is at a low level, the adjustment clock signal CK₀ is fixed at a low level, and the first through third selectors 62a through 62c (FIG. 14) included in the toggle adjustment circuit 59 select and output the first through third clock signals CK₁ through CK₃, respectively. In this case, the first through third circuit blocks 53a through 53c (FIG. 13) operate in synchronization with the first through third clock signals CK₁ through CK₃, respectively.

On the other hand, when the mode selection signal MODE is at a high level, the adjustment clock signal CK₀ changes in a manner similar to the clock signal CK, and the first through third selectors 62a through 62c output the adjustment clock signal CK₀ or a fixed value (at a low level). The toggle adjustment circuit 59 supplies the adjustment clock signal CK₀ to a circuit block 53j having been supplied with a clock signal TCᵢ whose toggle count TCᵢ is not at its maximum possible value M (where if i=1, j=a, if i=2, j=b, and if i=3, j=c). Accordingly, by suitably setting the mode selection signal MODE so as to be at a high level, it is made possible to cause the toggle counts TC₁ through TC₃ of the clock signals ck₁ through ck₃, which are respectively supplied to the first through third circuit blocks 53a through 53c, to approximate their respective possible maximum values M.

Transistors, which form logic cells included in each of the first through third circuit blocks 53a through 53c, deteriorate in accordance with a toggle count TCᵢ of a clock signal supplied to the circuit block. Therefore, if the toggle counts TC₁ through TC₃ of the clock signals ck₁ through ck₃, which are respectively supplied to the first through third circuit blocks 53a through 53c, are close to each other, delay times of circuits included in the first through third circuit blocks 53a through 53c vary in a manner similar to each other with the passage of time.

Accordingly, by suitably setting the mode selection signal MODE so as to be at a high level, it is made possible to cause delay times of circuits included in the first through third circuit blocks 53a through 53c to vary in a manner similar to each other with the passage of time. Therefore, even after the semiconductor integrated circuit is incorporated into the system, by adjusting the number of toggles of each clock signal, it is made possible to achieve an effect of preventing clock signals, which vary with frequencies different from each other, from being supplied. Once such clock signals are supplied, degrees of deterioration over time become different between transistors, so that a timing error occurs, resulting in a shorter service life of the semiconductor integrated circuit. The above effect is apparent particularly in a semiconductor integrated circuit having a function of reducing power consumption by ceasing to supply clock signals on a circuit block-by-circuit block basis.

(Sixth Embodiment)

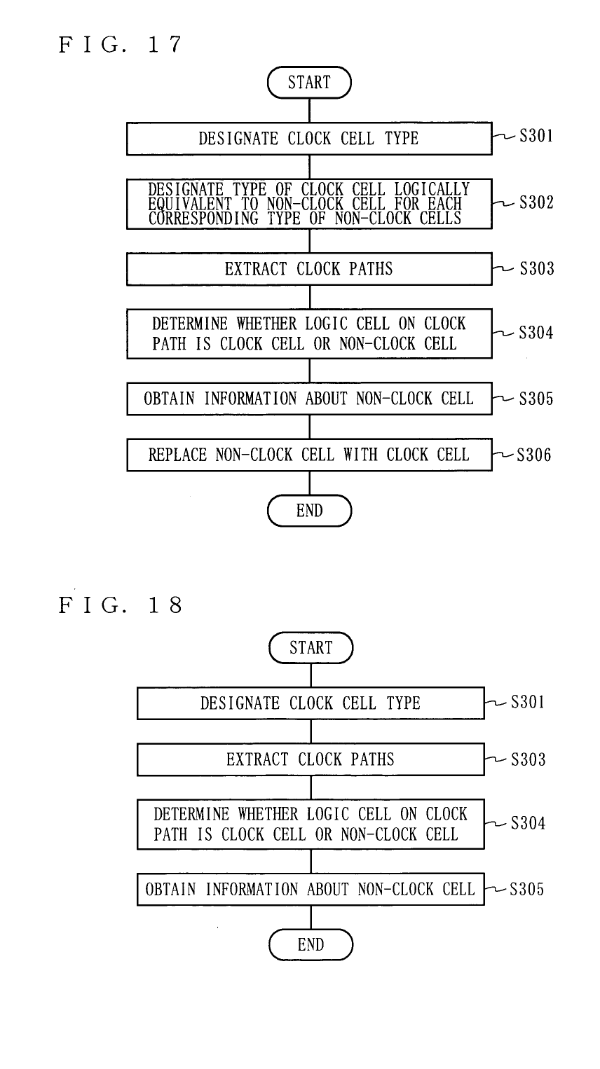

A sixth embodiment of the present invention is described with respect to a method for verifying or changing a clock circuit included in a semiconductor integrated circuit. FIG. 17 is a flowchart showing a method for designing a semiconductor integrated circuit in accordance with the present embodiment. The procedure shown in FIG. 17 is performed on a semiconductor integrated circuit after the completion of logic level design and before timing adjustment.

In the procedure shown in FIG. 17, firstly, the type of a logic cell which should be present on a clock path is designated from among all types of logic cells which can be used in designing the semiconductor integrated circuit (step S301). Hereinbelow, a logic cell of the type designated at step S301 is referred to as a “clock cell”, and other types of logic cells are referred to as “non-clock cells”. Note that at step S301, among all logic cells, only logic cells resistant to process variation are selectively designated as clock cells. Then, for each type of non-clock cells, a type of clock cell logically equivalent to the non-clock cell is designated (step S302).

Next, all clock paths are extracted from the semiconductor integrated circuit to be designed (step S303). Then, for each logic cell present on the extracted clock paths, a determination is made as to whether the logic cell is a clock cell or a non-clock cell (step S304). Then, various types of information are obtained for each logic cell determined at step S304 as being a non-clock cell (step S305). The information obtained at step S305 is referenced at subsequent steps of designing. Then, each logic cell determined at step S304 as being a non-clock cell is replaced by a clock cell designated at step S302 for each corresponding type of logic cell (step S306).

Therefore, in the method for designing a semiconductor integrated circuit in accordance with the present embodiment, it is possible to change a clock circuit included in the semiconductor integrated circuit such that only logic cells having a specific characteristic (e.g., logic cells resistant to process variation) are present on a clock path.

A flowchart shown in FIG. 18 can be obtained by removing steps S302 and S306 from the flowchart shown in FIG. 17. According to the procedure shown in FIG. 18, it is possible to readily verify that logic cells present on a clock path have a specific characteristic (e.g., they are resistant to process variation).

(Seventh Embodiment)

A seventh embodiment of the present invention is described with respect to a method for designing a clock circuit which takes account of a characteristic of a clock path. Described first is a method for designing a clock circuit which takes account of a difference in the number of stages of logic cells between clock paths. FIG. 19 is a flowchart showing a method for designing a semiconductor integrated circuit in accordance with the present embodiment. The procedure shown in FIG. 19 is performed on a semiconductor integrated circuit after the completion of logic level design and before timing adjustment.

In the procedure shown in FIG. 19, firstly, clock paths to all flip-flops are extracted from a semiconductor integrated circuit to be designed (step S401). Then, the number of stages of logic cells present on each of the extracted clock path is obtained as a characteristic of the clock path (step S402). Then, pairs of flip-flops are sequentially selected from the semiconductor integrated circuit to be designed, and for each pair of flip-flops, a difference in number of stages of logic cells present on clock paths between the pair of flip-flops is obtained (step S403).

Next, a time period corresponding to the obtained difference is set, as a design margin for accommodating the difference between clock paths, in timing constraints between each of the selected pairs of flip-flops (step S404). At step S404, for example, a time period proportional to the difference obtained at step S403 or a time period obtained by applying a prescribed function to the obtained difference may be set as the design margin. Note that at steps S403 and S404, a difference in the number of stages of logic cells between clock paths may be obtained only between each pair of flip-flops to which timing constraints have already been assigned, and a time period corresponding to the obtained difference may be set in the timing constraints.

Next, in accordance with the timing constraints in which the design margin has been set in a manner as described above, timing adjustment is performed on a circuit which supplies a clock signal and a data input signal to the flip-flops (step S405). At step S405, in order for clock skew to be less than a prescribed tolerance, for example, a process for adding or deleting a buffer, etc., to/from clock circuits, a process for redesigning a circuit for generating the data input signal, and a process for modifying a layout result are performed.

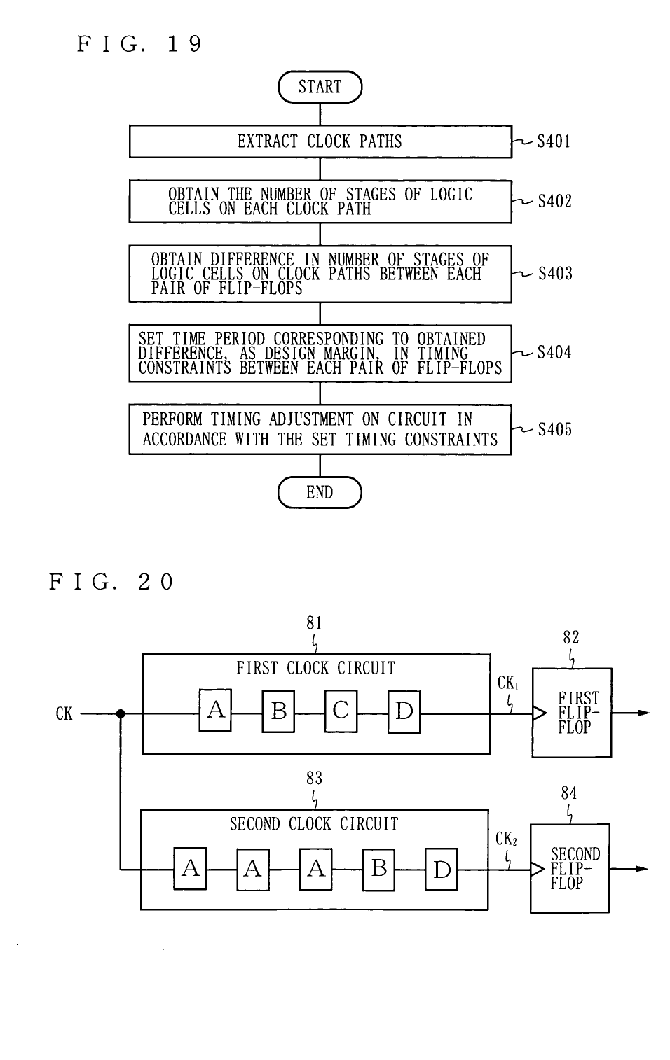

Next, a case where the procedure shown in FIG. 19 is applied to a semiconductor integrated circuit including a clock circuit shown in FIG. 20 is described in detail. The clock circuit shown in FIG. 20 includes a first clock circuit 81, a first flip-flop 82, a second clock circuit 83, and a second flip-flop 84. Each of the first and second flip-flops 82 and 84 operates in synchronization with a clock signal CK supplied thereto. Specifically, the first clock circuit 81 generates a first clock signal CK₁ based on the clock signal CK, and the first flip-flop 82 operates in synchronization with the first clock signal CK₁. The second clock circuit 83 and the second flip-flop 84 operate similar to the first clock circuit 81 and the first flip-flop 82, respectively.

Hereinbelow, a path from a supply source of the clock signal CK through the first clock circuit 81 to the first flip-flop 82 is referred to as a “first clock path”, and a path from the supply source of the clock signal CK through the second clock circuit 83 to the second flip-flop 84 is referred to as a “second clock path”. As shown in FIG. 20, four logic cells are present on the first clock path, and five logic cells are present on the second clock path. Note that in FIG. 20, letters assigned to logic cells, such as A, B, C, and D, represent types of the logic cells.

The number of stages of logic cells present on the first clock path is four, and the number of stages of logic cells present on the second clock path is five (step S402). Accordingly, a difference in the number of stages of logic cells between the first and second clock paths is one (step S403). Assuming that a design margin of 50 picoseconds (psec) is set for each difference of one stage, the design margin set for this case is 50 psec. Accordingly, the obtained value of 50 psec is set, as a design margin for accommodating a difference between clock paths, in timing constraints between the first and second flip-flops 82 and 84 (step S404). Next, in accordance with the timing constraints in which the design margin of 50 psec has been set, timing adjustment is performed on a clock circuit for supplying a clock signal and a data input signal to the first and second flip-flops 82 and 84 (step S405).

Described below is an effect achieved by using a design method according to the present embodiment to design a semiconductor integrated circuit including the clock circuit shown in FIG. 20. Conventionally, it is not known that a design margin for accommodating the number of stages of logic cells present on clock paths is set in timing constraints between flip-flops. In general, if there is a difference in the number of stages of logic cells between clock paths, the clock paths differ from each other in cause of delay time. Accordingly, a semiconductor integrated circuit is fabricated such that variation in delay time is likely to occur between the clock paths. Therefore, timing error due to manufacturing variability may easily occur in a semiconductor integrated circuit fabricated by a conventional method.

On the other hand, in the design method according to the present embodiment, the design margin for accommodating the number of stages of logic cells present on clock paths is set in timing constraints between flip-flops. Accordingly, even if there is a difference in the number of stages of logic cells between the clock paths, which results in a difference in cause of delay time between the clock paths, the difference in cause of delay time is accommodated by the set design margin. Therefore, a semiconductor integrated circuit is fabricated such that variation in delay time is unlikely to occur between the clock paths. Thus, a method for designing a semiconductor integrated circuit in accordance with the present embodiment provides a semiconductor integrated circuit in which timing error is not likely to occur.

The following variations are provided for the method for designing a semiconductor integrated circuit in accordance with the present embodiment. A first variation of the present embodiment uses, as a characteristic of a clock path, the number of logic cells present on the clock path obtained for each type of the logic cells. In order to implement a design method according to the first variation, at step S402 in FIG. 19, for each type of the logic cells, the number of logic cells, rather than the number of stages of logic elements, present on each clock path may be obtained as a characteristic of the clock path; at step S403, for each type of logic cells, a difference in the number of logic cells between the clock paths may be obtained; at step S404, a time period corresponding to the obtained difference may be set as the design margin.

A case where the method according to the first variation is applied to a semiconductor integrated circuit including the clock circuit shown in FIG. 20 is described in detail. On the first clock path, there is one logic cell each for types A, B, C, and D, while on the second clock path, there are three type-A logic cells, one type-B logic cell, and one type-D logic cell. Accordingly, a difference in the number of logic cells is two for type A and one for type C. If a design margin set per logic cell is 1.0% for type A, 1.1% for type B, 1.2% for type C, and 1.3% for type D, design margin MG for the entire clock circuit is obtained as 3.2% by the following expression (6),
MG=1.0×2+1.2×1=3.2 (6).

Accordingly, the timing adjustment is performed on the circuit for supplying signals to the first and second flip-flops 82 and 84, in accordance with timing constraints in which the obtained value of 3.2% is set as the design margin for accommodating a difference between clock paths.

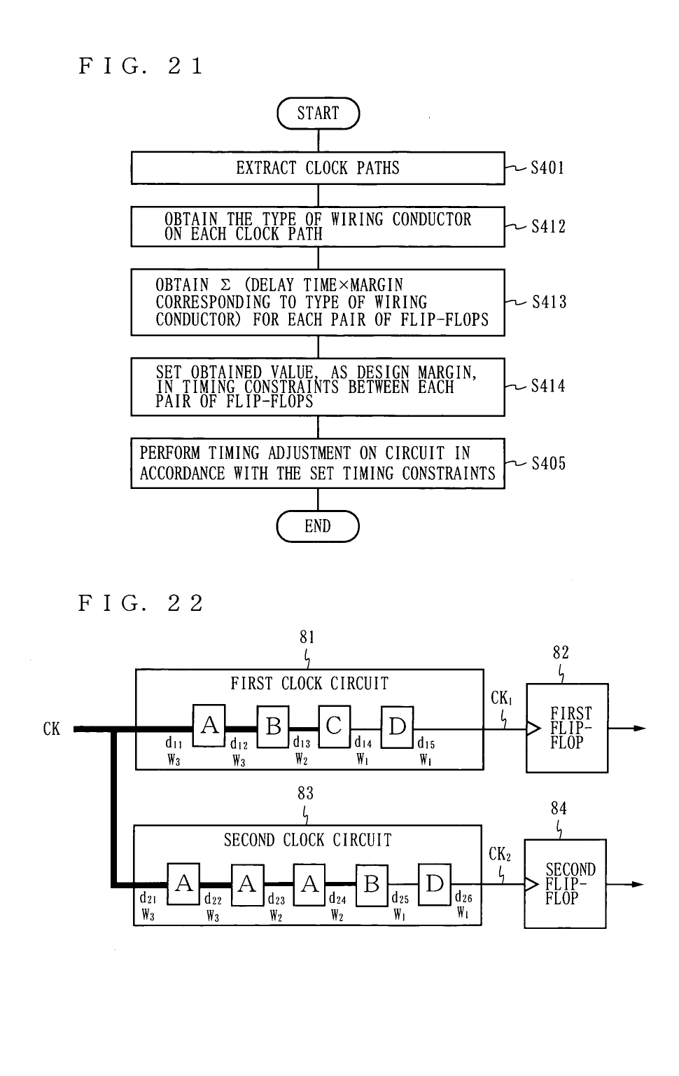

A second variation of the present embodiment uses, as a characteristic of a clock path, the type and delay time of a wiring conductor present on the clock path. FIG. 21 is a flowchart showing a method for designing a semiconductor integrated circuit in accordance with the second variation of the present embodiment. In the flowchart of FIG. 21, steps S401 and S405 are the same as those shown in the flowchart of FIG. 19.

In the procedure shown in FIG. 21, after clock paths are extracted (step S401), the type of a wiring conductor of each of the extracted clock path is obtained as a characteristic of the clock path (step S412). Then, pairs of flip-flops are sequentially selected from the semiconductor integrated circuit to be designed, and for each pair of flip-flops, fraction margin mg as defined by expression (7) shown below is obtained for each of a set of wiring conductors present on a clock path to one flip-flop and a set of wiring conductors present on a clock path to the other flip-flop, thereby obtaining the sum MGS of the two fraction margins (step S413).
mg=Σ(dᵢ×mᵢ) (7)

In the above-expression (7), dᵢ and mᵢ are respectively a delay time and a wiring margin of an i' th wiring conductor present on a clock path, and the sign Σ represents that summation of products of delay times and wiring margins is obtained for the clock path. The wiring margin mᵢ is determined in accordance with the type of a wiring conductor, e.g., 0.8 for a single-width wiring conductor, 0.4 for a double-width wiring conductor, 0.1 for a triple-width wiring conductor, etc.

Next, the obtained sum MGS of the fraction margins is set, as a design margin for accommodating a difference between clock paths, in timing constraints between each pair of flip-flops selected at step S413 (step S414), and timing adjustment is then performed (step S405).

A case where the method according to the second variation is applied to a semiconductor integrated circuit including a clock circuit shown in FIG. 22 is described in detail. FIG. 22 is a diagram showing the clock circuit of FIG. 20 together with delay times and widths of wiring conductors present on each clock path. In FIG. 22, sign d**(* denotes a numeric character) added to each wiring conductor denotes a delay time of the wiring conductor, and signs W₁ through W₃ denote a single-width wiring conductor, a double-width wiring conductor, and a triple-width wiring conductor, respectively (step S412).

If the wiring margin mᵢ is determined as exemplified above, i.e., 0.8 for a single-width wiring conductor, 0.4 for a double-width wiring conductor, and 0.1 for a triple-width wiring conductor, fraction margin mg₁ for the first clock path and fraction margin mg₂ for the second clock path are respectively obtained by expressions (8) and (9) shown below, and the sum MGS of the fraction margins mg₁ and mg₂ is obtained by expression (10) shown below (step S413).
mg₁=(d₁₁+d₁₂)×0.1+d₁₃×0.4+(d₁₄+d₁₅)×0.8 (8)
mg₂=(d₂₁+d₂₂)×0.1+(d₂₃+d₂₄)×0.4+(d₂₅+d₂₆)×0.8 (9)
MGS=(d₁₁+d₁₂+d₂₁+d₂₂)×0.1+(d₁₃+d₂₃+d₂₄)×0.4+(d₁₄+d₁₅+d₂₅+d₂₆)×0.8 (10)

Accordingly, timing adjustment is performed on a circuit for supplying a clock signal and a data input signal to the first and second flip-flops 82 and 84, in accordance with timing constraints in which a value obtained by the above expression (10) is set as the design margin for accommodating a difference between clock paths.

In addition to the foregoing, a pitch between wiring conductors present on a clock path or the presence or absence of shielding on the wiring conductors or wiring layers may be taken into consideration as a characteristic of the clock path. Further, it is optional as to how the design margin is obtained based on an obtained characteristic of the clock path. A method for designing a semiconductor integrated circuit in accordance with either of the above variations achieves an effect similar to that achieved by the design method described in conjunction with FIG. 19.

The present invention provides a semiconductor integrated circuit and a design method thereof, which possess characteristics advantageous in supplying a clock signal over a conventional semiconductor integrated circuit and a conventional design method, and therefore can be applied to a variety of types of semiconductor integrated circuits, e.g., a semiconductor integrated circuit mainly formed by logic circuits, a semiconductor integrated circuit including both logic circuits and memory circuits, etc., and methods for designing such semiconductor integrated circuits.

While the invention has been described in detail, the foregoing description is in all aspects illustrative and not restrictive. It is understood that numerous other modifications and variations can be devised without departing from the scope of the invention.

1. A semiconductor integrated circuit operating in synchronization with a clock signal, the semiconductor integrated circuit comprising:
a plurality of storage cells;
a clock circuit for generating, based on a clock signal supplied thereto, a clock signal to be supplied to each of the storage cells; and
a combinational circuit for generating, based on a value stored in each of the storage cells, a data input signal to be supplied to each of the storage cells,
wherein the clock circuit includes logic cells formed by transistors of a unified size.

2. The semiconductor integrated circuit according to claim 1, wherein the logic cells included in the clock circuit are formed by transistors, each having a uniform rectangular-shaped diffusion region.

3. A semiconductor integrated circuit design method for designing a semiconductor integrated circuit operating in synchronization with a clock signal, the method comprising the steps of:
designing a circuit block having a clock circuit which includes a first clock cell operating under a first operating condition, the circuit block operating under the first operating condition;
replacing the first clock cell included in the clock circuit of the circuit block by a second clock cell which is equivalent to the first clock cell in an input capacitance, a cell-specific delay and a driving capability, the second clock cell operating under a second operating condition; and
designing a semiconductor integrated circuit which includes the circuit block including the second clock cell, the semiconductor integrated circuit operating under the second operating condition.

4. The semiconductor integrated circuit design method according to claim 3, wherein the first and second operating conditions each are related to a threshold voltage.

5. The semiconductor integrated circuit design method according to claim 3, wherein the first are second operating condition each are related to a supply voltage.

6. A semiconductor integrated circuit design method for designing a semiconductor integrated circuit operating in synchronization with a clock signal, the method comprising the steps of:
obtaining the number of toggles in a prescribed service life for each clock signal to be supplied to storage cells included in the semiconductor integrated circuit;
obtaining, based on the obtained number of toggles, a quantity of delay variation at an expiration of the service life for said each clock signal;
obtaining a difference in the quantity of delay variation between a clock signal to be supplied to a first storage cell and a clock signal to be supplied to a second storage cell;
setting the obtained difference, as a design margin for accommodating a delay time variation due to deterioration over time, in timing constraints between the first and second storage cells; and
performing a timing adjustment on a circuit for supplying a signal to the first and second storage cells, in accordance with the timing constraints in which the design margin has been set.

7. A semiconductor integrated circuit operating in synchronization with a clock signal, the semiconductor integrated circuit comprising:
a plurality of circuit blocks;
a clock circuit for generating, based on a clock signal supplied thereto, a clock signal to be supplied to each of the circuit blocks;
a toggle counting circuit for counting the number of toggles of the clock signal to be supplied to each of the circuit blocks; and
a toggle count output circuit for outputting the number of toggles.

8. A semiconductor integrated circuit operating in synchronization with a clock signal, the semiconductor integrated circuit comprising:
a plurality of circuit blocks;
a clock circuit for generating, based on a clock signal supplied thereto, a clock signal to be supplied to each of the circuit blocks;
a toggle counting circuit for counting the number of toggles of the clock signal to be supplied to each of the circuit blocks; and
a toggle adjustment circuit for supplying an adjustment clock signal to a circuit block to which a clock signal whose number of toggles is relatively low is supplied, the adjustment clock signal being different from the clock signal supplied to the clock circuit.

9. A semiconductor integrated circuit design method for designing a semiconductor integrated circuit operating in synchronization with a clock signal, the method comprising the steps of:
designating a type of logic cells which should be present on a clock path; and
determining for each clock path included in the semiconductor integrated circuit whether logic cells present on the clock path are of the designated type.

10. The semiconductor integrated circuit design method according to claim 9, further comprising the steps of:
designating, for each type of logic cell which should not be present on a clock path, a type of logic cell which should be present on the clock path and is logically equivalent to the logic cell which should not be present on the clock path; and
replacing, based on a result of the determining step for each clock path included in the semiconductor integrated circuit, a logic cell, which should not be, but is, present on the clock path, with a logic cell, which should be present on the clock path and whose type corresponds to that of the logic cell, which should not be, but is, present on the clock path.

11. A semiconductor integrated circuit design method for designing a semiconductor integrated circuit operating in synchronization with a clock signal, the method comprising the steps of:
obtaining prescribed characteristics of each clock path to storage cells included in the semiconductor integrated circuit;
obtaining a design margin in a prescribed manner based on said prescribed characteristics of a first clock path to a first storage cell and said prescribed characteristics of a second clock path to a second storage cell;
setting the obtained design margin, as a design margin for accommodating a difference between clock paths, in timing constraints between the first and second storage cells; and
performing a timing adjustment on a circuit for supplying a signal to the first and second storage cells, in accordance with the timing constraints in which the obtained design margin has been set.

12. The semiconductor integrated circuit design method according to claim 11, wherein:
said prescribed characteristics include the number of stages of logic cells present on the clock path; and
the step of obtaining a design margin obtains the design margin based on a difference in the number of stages of logic cells between the first and second clock paths.

13. The semiconductor integrated circuit design method according to claim 11, wherein:
said prescribed characteristics include the number of each type of logic cells present on the clock path; and
the step of obtaining a design margin obtains the design margin based on a difference in the number of each type of logic cells between the first and second clock paths.

14. The semiconductor integrated circuit design method according to claim 11, wherein:
said prescribed characteristics include a type of wiring conductors present on the clock path; and
the step of obtaining a design margin obtains the design margin based on a type and a delay time of wiring conductors present on the first clock path and a type and a delay time of wiring conductors present on the second clock path.
